(19) United States
(12) Patent Application Publication
(10) Pub. No.: US 2026/0331389 A1
(43) Pub. Date: Oct. 22, 2026

(54) SYSTEMS AND METHODS FOR RADIO FREQUENCY DIGITAL TUNER CAPACITOR (RF DTC) DEVICES

(71) Applicant: Nanusens SL, Cerdanyola del Vallès (ES)

(72) Inventors: Thomas Hanley, London (GB); Gerard TAULATS BRAOS, Cerdanyola del Vallès (ES); Marco Antonio LLAMAS MOROTE, Cerdanyola del Vallès (ES); Josep Montanyà i Silvestre, Cerdanyola del Vallès (ES)

(73) Assignee: Nanusens SL, Cerdanyola del Vallès (ES)

(21) Appl. No.: 19/654,648

(22) Filed: Apr. 22, 2026

Related U.S. Application Data
(60) Provisional application No. 63/792,790, filed on Apr. 22, 2025.

(51) Int. Cl. H01H 1/00; H01H 3/26

(52) U.S. Cl. CPC H01H 1/0036; H01H 3/26

(57) ABSTRACT

A RF-MEMS capacitive switch including at least one stator having stator teeth and at least one rotor having rotor teeth. Actuation being provided by an electrostatic force between the at least one stator and the at least one rotor when a voltage difference is applied between them. A central apex is connected to the at least one rotor and suspended by means of a plurality of meander springs positioned at distal ends of the central apex.

### CROSS-REFERENCE TO RELATED APPLICATIONS

This application claims priority to and the benefit of U.S. Provisional Application No. 63/792,790, filed on Apr. 22, 2025, and entitled “RADIO FREQUENCY DIGITAL TUNER CAPACITOR (RF DTC) DEVICES,” the entire contents of which are incorporated herein by reference.

### TECHNICAL FIELD

The present disclosure relates to semiconductor devices and, more particularly, to MEMS-based capacitive switches.

### BACKGROUND

RF MEMS switches are tiny switches made through conventional MEMS fabrication technology. They consume low power and function like a light switch or ohmic switch by opening or closing a contact to transmit a signal across the switch. The mechanical components of the switch are only a few microns in size, and the signal transmitted is in the radio frequency range. An RF Digital Tunable Capacitor (DTC) is typically made with several capacitive switches in parallel.

### SUMMARY

The application, in various implementations provides systems, architectures, and methods for NNS RF MEMS capacitive switch implementations.

Two primary specifications for devices, architectures, and methods include: 1) Capacitance ratio: Ratio of capacitance in the ON to OFF state; and 2) Power Handing where the maximum input RF power that can be supported without failure or performance degradation of the device. These primary specifications tend to have an inverse relationship with regard to design features, as features that improve the device robustness to input power tend to increase parasitic capacitance, reducing capacitance ratio. Practical market demand places the values required for these specifications typically at: Capacitance ratio ≥5; and Maximum Peak Voltage ≥80V.

Various implementations may include fabrication of a MEMS device via the back-end metal layers of any solid state or semiconductor process including, for example, a CMOS process. Fabrication may include, for example, compound processes, like GaAs, GaN and SiGe among others without limitation. In all these cases etching may be performed with vHF or other techniques as a post-processing vHF etching. However, etching processes other than vHF may be used for MEMS capacitive switching devices and systems disclosed herein. Also, RF DTC devices may be built and/or fabricated using MEMS manufacturing processes other than vHF etching. For example, RF DTC devices may may be formed by building a MEMS process with a large number of structural layers and then implementing the devices. Various implementations also include MEMS and/or RF DTC devices configured to withstand electrostatic discharge (ESD).

In one aspect, an RF-MEMS capacitive switch includes at least one stator having stator teeth and at least one rotor having rotor teeth, where actuation is provided by an electrostatic force between the at least one stator and the at least one rotor when a voltage difference is applied between them. The capacitive switch also includes a central apex connected to the at least one rotor and suspended by means of a plurality of meander springs positioned at distal ends of the central apex.

The capacitive switch may have a capacitance ratio ≥5 and maximum peak voltage ≥80V. The capacitive switch may include an etch-limiting capacitive anchor having a flap implemented on a metal layer. The flap may be implemented on the M2 layer. The switch may include a pillarless capacitive anchor.

The at least one rotor and the at least one stator may be configured to reduce the electrostatic force needed to actuate the capacitive switch. In one implementation, material in at least one of the rotor teeth and stator teeth that does not overlap its opposing teeth does not include a full stack of metals. In another implementation, the switch includes a support beam that does not include a full stack of metals. In a further implementation, the switch includes a support beam that is notched by an amount equal to the size of a gap directly in front of a tooth of the rotor teeth from an opposing tooth of the stator teeth. In yet another implementation, material from all layers of the capacitive switch are present in a portion of a tooth of the rotor teeth that overlaps an adjacent tooth of the stator teeth at the point of maximum overlap with the capacitive switch is in an ON state, but is minimized in all layers of the capacitive switch in regions that do not overlap.

In another aspect, a MEMS-based device includes at least one stator having stator teeth; and at least one rotor, having rotor teeth, with actuation providing an electrostatic force between the at least one stator and the at least one rotor when a voltage difference is applied between them.

The MEMS-based device may have a capacitance ratio ≥5 and maximum peak voltage ≥80V. The MEMS-based device may have an etch-limiting capacitive anchor including a flap. The flap may be implemented on the M2 metal layer. The MEMS-based device may have a pillarless capacitive anchor.

The at least one rotor and the at least one stator may be configured to reduce the electrostatic force needed to actuate the MEMS-based device. In one implementation, material in at least one of the rotor teeth and stator teeth that does not overlap its opposing teeth does not include a full stack of metals. In another implementation, the MEMS-based device has a support beam that does not include a full stack of metals. In a further implementation, the MEMS-based device has a support beam that is notched by an amount equal to the size of a gap directly in front of a tooth of the rotor teeth from an opposing tooth of the stator teeth. In yet another implementation, the MEMS-based device is configured where material from all layers of the MEMS-based device is present in a portion of a tooth of the rotor teeth that overlaps an adjacent tooth of the stator teeth at the point of maximum overlap with the MEMS-based device is in an ON state, but minimized in all layers of the capacitive switch in regions that do not overlap. The MEMS-based device may have a stopper positioned adjacent to a tooth of at least one of the rotor teeth and the stator teeth.

A reading of the following detailed description and a review of the associated drawings will make apparent the advantages of these and other structures. Both the foregoing general description and the following detailed description serve as an explanation only and do not restrict aspects of the disclosure as claimed.

### BRIEF DESCRIPTION OF THE DRAWINGS

Reference to the detailed description, combined with the following figures, will make the disclosure more fully understood, wherein:

FIG. 1 shows a capacitive anchor design;

FIG. 2 shows an etch-limiting capacitive anchor with flap present in the M2 layer;

FIG. 3 shows a pillarless mechanical anchor implementation;

FIG. 4 shows a minimal single-plate pillarless capacitive anchor;

FIG. 5 shows an annotated tope view of an arbitrary quantity of rotor and stator teeth in the ON state;

FIGS. 6A and 6B show top and side views of an interdigitated rotor-stator pair design in the ON state;

FIG. 7 shows a side view of an interdigitated rotor-stator pair in the ON state with grounded top and bottom metal layers that contribute to the stator parasitic capacitance;

FIGS. 8A and 8B show further top and 3D views of an interdigitated rotor-stator pair design in the ON state of implementation 3;

FIG. 9 shows a side view of the interdigitated rotor-stator pair of FIGS. 8A and 8B including grounded top and bottom metals that contribute to the stator parasitic capacitance of implementation 3;

FIGS. 10A and 10B provide a 3D geometry comparison of reference and the design of implementation 3;

FIG. 11 provides a side-by-side views of geometries including feature D of implementation 3 to a reference;

FIG. 12 provides another side-by-side comparison of geometries of implementation 3 to a reference;

FIG. 13 shows a Y-direction force component acting on a rotor in a reference design;

FIG. 14 shows a graph of force components and total force vs gap, d, for a reference rotor-stator design;

FIG. 15 shows a graph of force components and total Y-direction force vs gap, d, for implementation 3 rotor-stator design;

FIG. 16 shows a graph comparison of total Y-direction force between a reference rotor-stator design and the implementation 3 design;

FIG. 17 shows a graph of force vs. voltage for the reference and implementation 3 designs;

FIGS. 18A and 18B show X-direction and Y-direction deflection comparisons between the reference and implementation 3 designs;

FIG. 19 shows the annotated zero force ON state rotor and stator half tooths;

FIG. 20 shows forces acting on the stator at a position of displacement marginally past the ON state;

FIGS. 21A and 21B show simulated capacitance and force (at 1V) of the design shown in FIG. 19;

FIG. 22 shows a single-stator double-rotor implementation;

FIG. 23 shows a balanced electrostatic force on a stator due to opposing rotors;

FIGS. 24A, 24B, and 24C show various views of a compliant mechanism implementation of a single-stator-double-rotor design;

FIGS. 25A and 25B show device deformation in the OFF and ON states;

FIG. 26 shows a perspective view inside and outside of a MEMS cavity;

FIG. 27 shows a standard RF track arrangement with 1 track per stator traveling out of the MEMS cavity;

FIG. 28 shows an RF track routed through a MEMS apex with sufficient space that allows for movement of the apex;

FIG. 29 shows a perspective view of a high capacitance density, double-apex RF MEMS capacitance switch;

FIG. 30 shows a diagram of a high-capacitance density, double-apex capacitive switch;

FIG. 31 shows stopper types and their placement;

FIG. 32 shows an example of a stopper positioned between teeth and only connected to top metal in the ON and OFF states;

FIG. 33 shows an example of a “pillar-type” stopper spanning between a bottom metal layer and a top metal layer, and positioned outside of the stator;

FIGS. 34A and 34B show examples of different stopper shapes respectively;

FIG. 35 shows another example of pillar stopper placement between teeth or outside of the stator region;

FIG. 36 shows the electrostatic forces experienced by the outermost teeth;

FIG. 37 shows deflection of the outermost tooth due to a potential difference between the rotor and stator;

FIG. 38 shows stopper placement to prevent failure due to deflection of the outermost tooth;

FIG. 39 shows teeth of increased width;

FIG. 40 shows a device with a single MEMS stopper implementation enabling an intermediate ON state;

FIG. 41 shows a device with multiple MEMS stoppers and multiple intermediate ON states;

FIG. 42 shows stepped actuation of an RF MEMS capacitive switch;

FIG. 43 shows an implementation of tensile aligners;

FIG. 44 shows a simulation of deformation of a stator beam with a two layer metal reinforcement;

FIGS. 45A and 45B show examples of standard rectangular reinforcement vs. tapered reinforcement;

FIG. 46 shows peak voltage limiting RF track with MEMS variable coupling capacitance;

FIG. 47 shows a device including interdigitated DC actuators and interdigitated pull-off actuators; and

FIG. 48 shows an example of a ball grid array (BGA) style chip with a star topology DTC.

### DETAILED DESCRIPTION

In the following description, like components have the same reference numerals, regardless of different illustrated implementations. To illustrate implementations clearly and concisely, the drawings may not necessarily reflect appropriate scale and may have certain structures shown in somewhat schematic form. The disclosure may describe and/or illustrate structures in one implementation, and in the same way or in a similar way in one or more other implementations, and/or combined with or instead of the structures of the other implementations.

In the specification and claims, for the purposes of describing and defining the invention, the terms “about” and “substantially” represent the inherent degree of uncertainty attributed to any quantitative comparison, value, measurement, or other representation. The terms “about” and “substantially” moreover represent the degree by which a quantitative representation may vary from a stated reference without resulting in a change in the basic function of the subject matter at issue. Open-ended terms, such as “comprise,” “include,” and/or plural forms of each, include the listed parts and can include additional parts not listed, while terms such as “and/or” include one or more of the listed parts and combinations of the listed parts. Use of the terms “top,” “bottom,” “above,” “below” and the like helps only in the clear description of the disclosure and does not limit the structure, positioning and/or operation of the disclosure in any manner.

Certain aspects of the present disclosure describe illustrative devices and fabrication techniques that enable more robust, responsive, and reliable RF-MEMS-based capacitive switching.

### Implementation 1—Etch-Limiting Capacitive Anchor

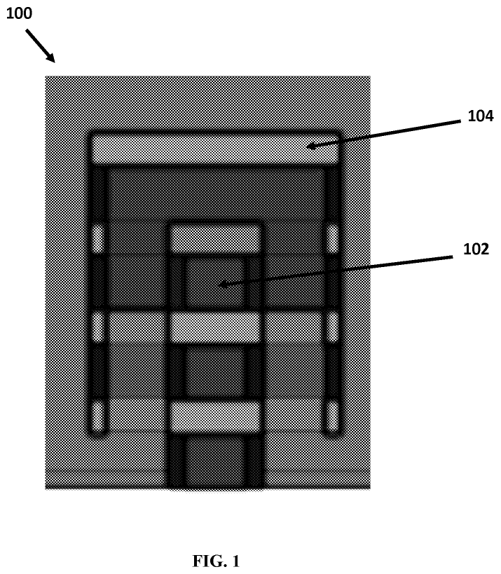

FIG. 1 shows a capacitive anchor 100 that features a central pillar 102, an outer cap 104, and residual silicon oxide dielectric (post-vapour HF etch) connecting the two. The purpose is to provide anchorage for mechanical components that are required to be electrically isolated from Metal 1 (the first metal layer).

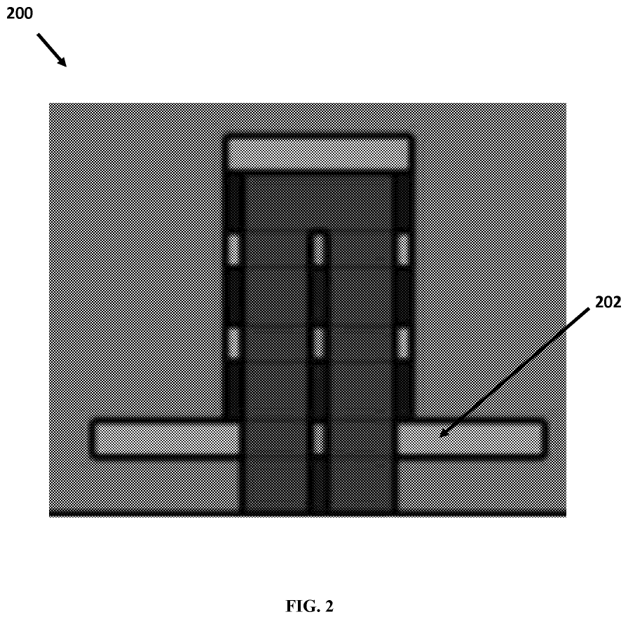

The amount of silicon dioxide remaining between the pillar 102 and the cap 104 dictates both the capacitance (parasitic to the RF MEMS device) and the mechanical robustness of the anchor 100. Due to expected cross-wafer and wafer-to-wafer etch rate variations within the vapour HF etch, the amount of silicon dioxide remaining can vary per capacitive anchor 100. The primary impact of this is an anchor-to-anchor variation in robustness leading to part-to-part quality and reliability issues. Implementation 1 is a novel development of the “etch-limiting capacitive anchor” that eliminates this issue by the addition of an extended flap, as depicted in FIG. 2.

FIG. 2 shows an etch-limiting capacitive anchor 200 with flap 202 present in the M2 layer. The addition of the flap 202, which could be implemented in any metal layer, prevents the etching of the silicon dioxide within the central section of the capacitive anchor 200 leading to uniform robustness properties of all anchors cross-wafer and wafer-to-wafer. This is achieved due to the dimensions of the flap exceeding the lateral etch rate of the vapour HF with the effect that the completion of the etch always exists within the flap region and does not extend up the column of silicon dioxide between the pillar and cap. This enables the remaining silicon dioxide to securely attach the pillar to the cap, greatly increasing the force it is able to sustain before failure.

### Implementation 2—Pillarless Capacitive Anchor

Implementation 2 is an extension upon the concept of the etch-limiting capacitive anchor presented in Implementation 1. The additional silicon dioxide remaining in the capacitive anchor, whilst beneficial to mechanical robustness, increases the capacitance between the pillar and cap, which is realized at device-level as a parasitic capacitance, reducing capacitance ratio. In order to reduce the pillar-to-cap capacitance, implementations 2 presents a pillarless capacitive anchor, utilizing the etch-limiting flap to ensure silicon dioxide remains within the core of the cap to mechanically anchor it to the M1 layer.

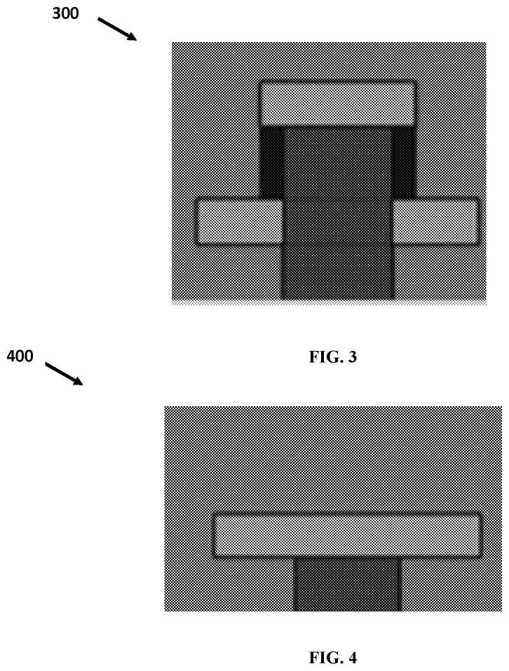

FIG. 3 presents a typical implementation of the pillar less capacitive anchor 300. Further to this, in some instances a single plate capacitive anchor 400 will be the preferred and most minimalist solution. This is presented in FIG. 4, providing a plate on silicon dioxide anchored plate on which to build an electrically isolated structure that requires a minimal footprint.

### Implemenation 3—Optimal RF-MEMS Interdigitated Capacitive Electrode Pair Design (Optimized to Maximize Capacitance and Minimize, or Achieve Net-Zero, Electrostatic Force by Self-Alignment).

Power handling capability is generally limited by mechanical deflection of the rotor-stator pair leading to a short circuit failure of the device. The mechanical deflection is caused by the attractive electrostatic force between the rotor and stator. The amount of deflection is determined by the ratio of force to stiffness, therefore, a reduction in deflection can be obtained either by an increase in rotor and stator stiffness or a decrease in electrostatic force. An increase in stiffness is generally obtained by adding more material, that is, making the reinforcement beams wider. However, adding material to the terminal connected to the RF signal input is generally detrimental to capacitance ratio, as it contributes additional static capacitance in the OFF state.

Implementation 3 therefore presents an approach to reduce the electrostatic force, rather than increasing the stiffness, by way of a set of rotor-stator pair design principles that can reduce the electrostatic force significantly, in some instances reducing to a net zero force on the rotor and/or stator. This can be achieved with a negligible impact on capacitance ratio compared to a standard interdigitated rotor-stator pair. This is accomplished by utilizing a “self-aligned” state of the rotor-stator pair that results in a force minimum. The examples provided for this concept relate to the Y-direction only, however, the concept can be employed in any of the principal directions and examples of how this can be used in the X- or Z-directions are also provided.

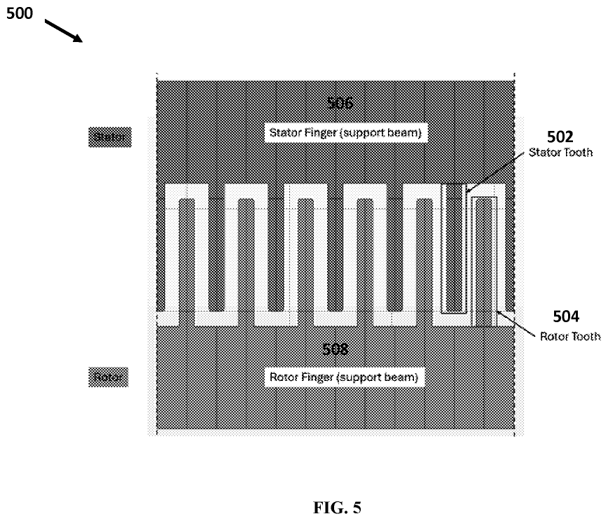

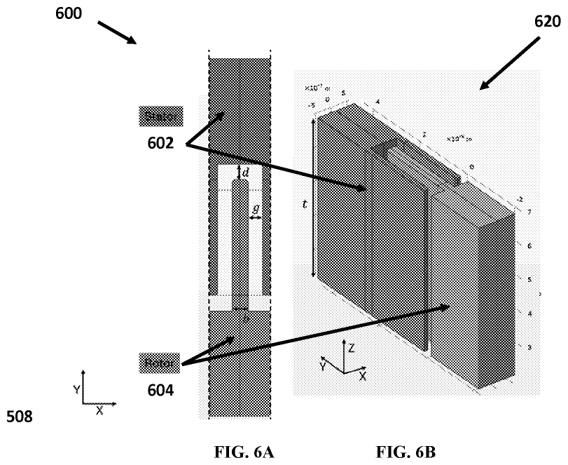

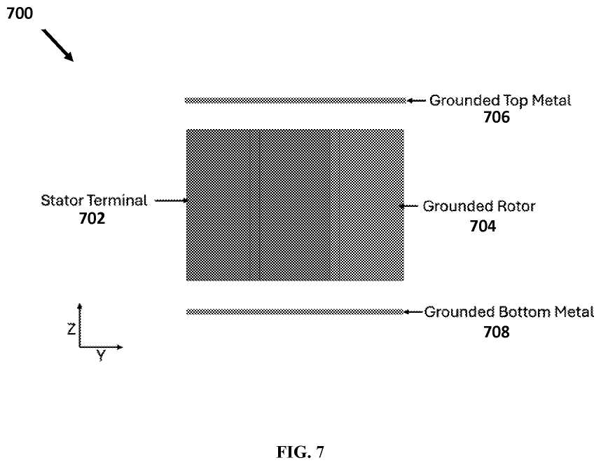

The standard rotor-stator pair design in the position of desired maximum overlap, the “ON state”, is shown in FIGS. 5-7. FIG. 5 shows a rotor-stator pair 500 including a Stator tooth 502, rotor tooth 504, Stator finger 506, and rotor finger 508. FIG. 6 shows a rotor-stator pair 600 including a stator 602 and rotor 604. FIG. 7 shows a side view of rotor-stator pair 700 including a stator terminal 702, grounded rotor 704, grounded top metal layer 706, and grounded bottom metal layer 708.

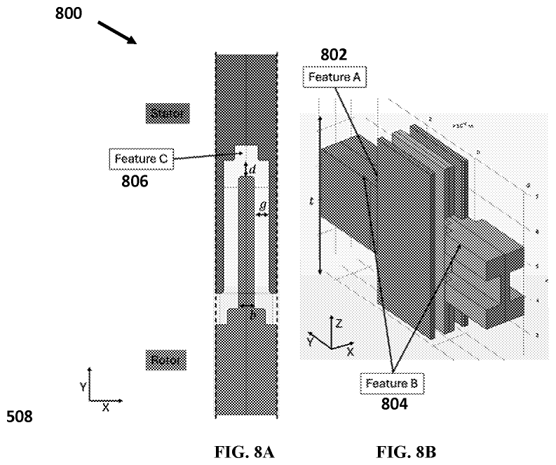

An example design to demonstrate implementation 3 is shown in FIGS. 8A-12, although other possible incarnations are presented later. The primary features are described below.
Feature A 802: At the point of desired maximum overlap (dictated by the designed placement of mechanical stoppers and DC actuator travel), the material in the teeth that does not overlap the opposing tooth and is used to connect the tooth to the finger (support beam), does not include the full stack of metals (e.g. in this implementation is limited to half the tooth height).
Feature B 804: The finger (support beam) does not include the full stack of metals (e.g. in this implementation is limited to half the tooth height).
Feature C 806: The finger (support beam) is notched by an amount approximately equal to the size of the gap, d, directly in front of the tooth from the opposing rotor/stator.
Feature D 1006: Material from all layers is present in the portion of the tooth that overlaps the adjacent tooth at the point of maximum overlap (the “ON state”) but minimized as far is possible in all layers in regions that do not overlap.

FIGS. 8A and 8B shows top and 3D views 800 of the implementation 3 interdigitated rotor-stator pair design in the ON state annotated with relevant dimensions and displaying described features A 802, B 804, and C 806.

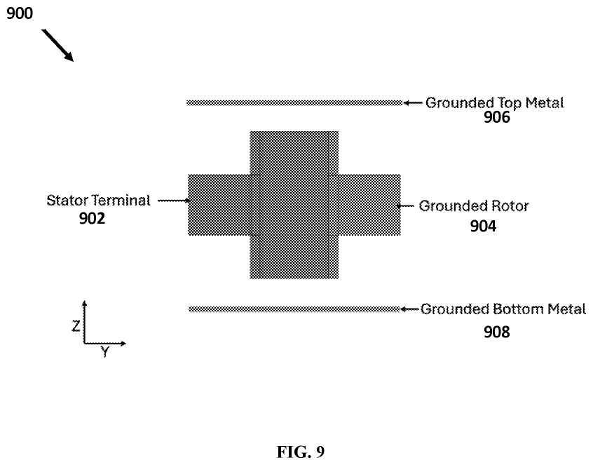

FIG. 9 shows a side view 900 of the implementation 3 interdigitated rotor-stator pair design in the ON state displaying stator terminal 902, grounded rotor 904, and grounded top 906 and bottom 908 metals that contribute to the stator parasitic capacitance.

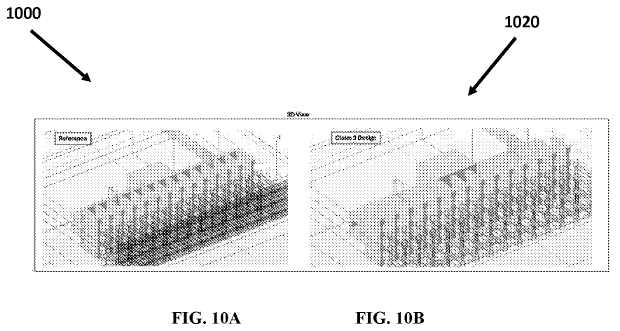

FIGS. 10A and 10B provide a 3D geometry comparison of reference 1000 and the design 1020 of implementation 3.

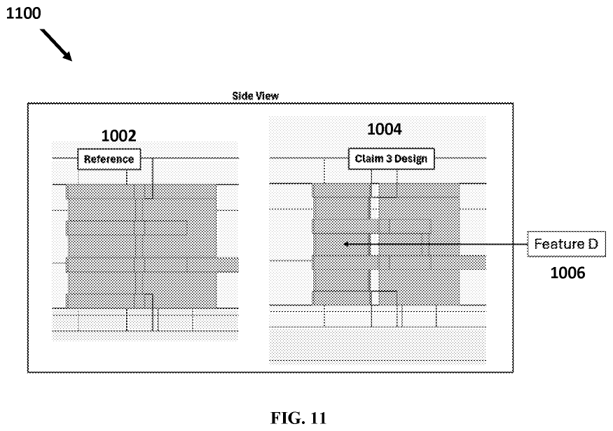

FIG. 11 provides a side-by-side comparison 1100 of reference geometry 1002 vs the implementation 3 geometry 1004 including feature D 1006.

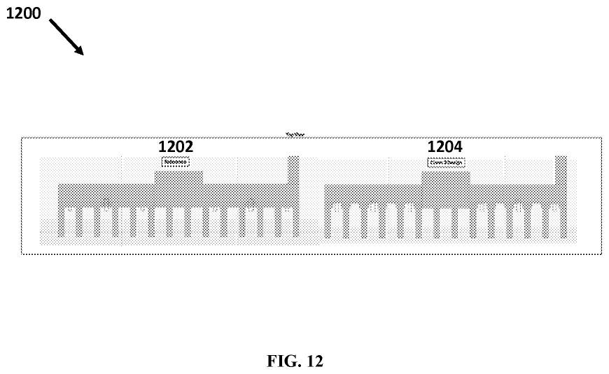

FIG. 12 provides another side-by-side comparison 1200 of geometries of implementation 3 geometry 1204 to a reference geometry 1202.

The physical justification for the benefits of this design is provided in the following. Considering the standard rotor-stator pair design of FIGS. 5-7, the total electrostatic force in the Y-direction for an interdigitated rotor-stator pair has two main components:
A force arising between the tips of the teeth and the opposing supporting beam, maximizing the tooth tip-to-beam capacitance, F_{TIP}.
A force arising on the leading edges of the teeth acting to align the teeth to maximize the tooth-to-tooth capacitance, F_{SIDE}.

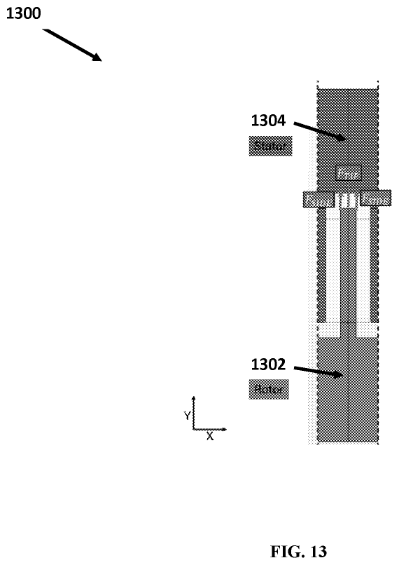

FIG. 13 shows a Y-direction force component acting on a rotor in a reference design 1300. The forces F_{TIP} and F_{SIDE} are described by equations 1 and 2, respectively [1]. Where Eo is the permittivity of free space, n is the number of teeth, t is the tooth thickness, b is the tooth width and d and g correspond to the gap distances annotated in FIG. 6.

$${F}_{TIP} = \frac{{ε}_{0} n t b {V}_{RMS}^{2}}{{d}^{2}} \qquad ( 1 )$$

$${F}_{SIDE} = \frac{{ε}_{0} n t {V}_{RMS}^{2}}{g} \qquad ( 2 )$$

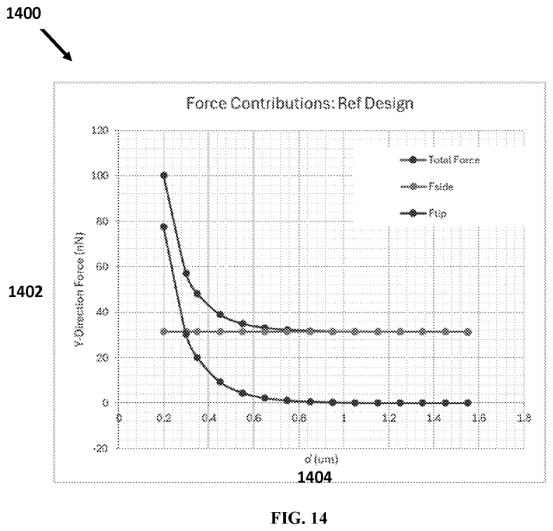

The motion of the rotor relative to the stator in operation causes the gap, d, to vary, reaching a minimum at the point of maximum desired overlap, the ON state, (dictated by the placement of mechanical stoppers and DC actuator travel). The gap, g, is constant for a given design. The force components F_{TIP} and F_{SIDE} as well as the total force are plotted as a function of gap, d, in FIG. 14 for the standard rotor-stator design of FIGS. 5-7.

FIG. 14 shows a graph 1400 of force components 1402 vs. 1404 including total force vs gap, d, for a reference rotor-stator design.

In order to maximize the device power handling, it is advantageous to minimize the total force at the position of maximum desired overlap, that is, the “ON State”. The design features of the implementation 3 design presented in FIGS. 8-12 achieve this in the following ways:
Feature A 802: The removal of material ahead of the opposing advancing tooth tip acts to decrease the rate of capacitance increase,

$$\frac{d C ( Y )}{d Y} ,$$

as the tooth advances beyond the desired maximum overlap. As electrostatic force is governed by Equation 4 (derived from the energy expression of Equation 3), this leads to a decrease in the F_{SIDE} force component in the ON state compared to other interdigitated tooth positions, or values of d.
Feature B 804: Decreases the effective thickness, t, in Equation 1, decreasing the F_{TIP} component of force
Feature C 806: Acts to increase the value of d in Equation 1, decreasing the F_{TIP} component of force.
Feature D 1006: Has an identical effect to Feature A, removing material ahead of the advancing tooth.

$$E = \frac{1}{2} C ( Y ) {V}_{RMS}^{2} \qquad ( 3 )$$

$${F}_{{E}_{Y}} = \frac{1}{2} \frac{dC ( Y )}{dY} {V}_{RMS}^{2} \qquad ( 4 )$$

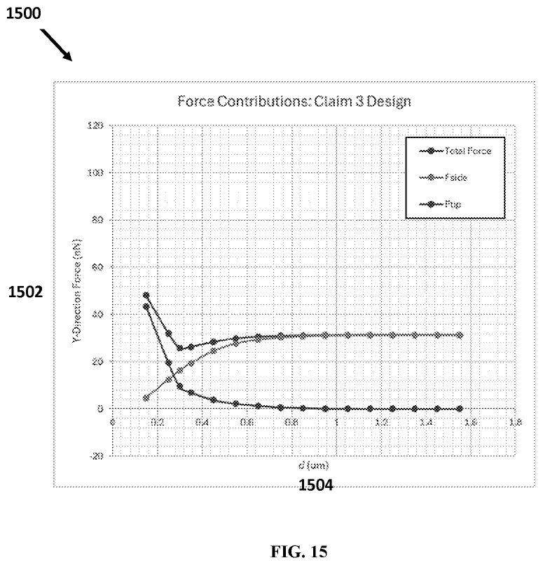

FIG. 15 shows a graph 1500 of the force components 1502 vs 1504 and total force for the implementation 3 design. A force minimum is achieved in the ON State, which also corresponds to the point of maximum capacitance.

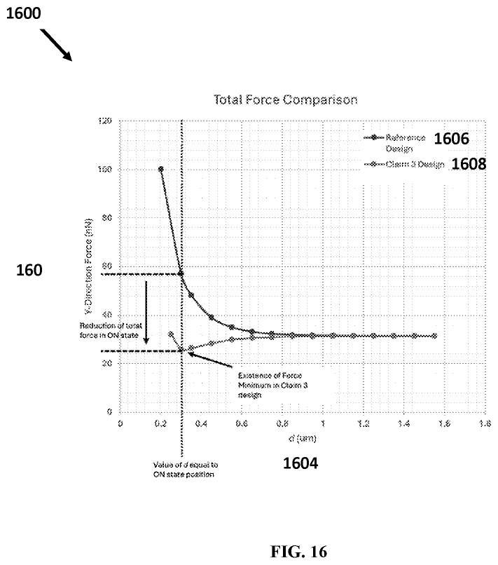

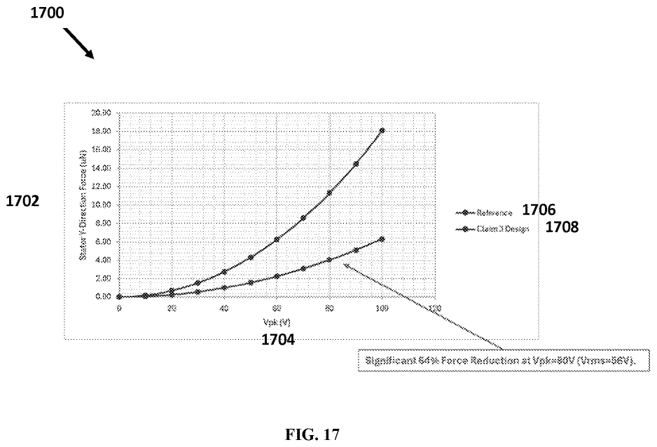

FIG. 16 shows a graph 1600 that compares the total force vs gap, d, of the design in FIG. 8 1608 compared to the standard design 1606 showing a 64% force reduction in the ON state at a peak voltage of 80V.

Whilst the electrostatic force is significantly reduced by the designs of implementation 3, the ON State capacitance and capacitance ratio are minimally impacted. As the main contributor to capacitance in the interdigitated capacitor is the tooth-tooth lateral area overlap, and this area is maintained in the implementation 3 designs, the capacitance reduction in the ON state is only minimally reduced. Furthermore, due the reduced material in the finger and other supporting structures, the parasitic capacitance in the OFF state is also reduced, leading to a negligible impact on capacitance ratio. The capacitance values and capacitance ratios of the two designs are compared in Table 1.

TABLE 1

| | Reference | Design shown in FIG. 8 |
|---|---|---|
| Coff | 12.7 | 12.0 |
| Con | 31.4 | 29.2 |
| Cratio | 2.47 | 2.43 |

FIG. 17 shows a graph 1700 of the simulated force 1702 vs voltage characteristics 1704 for the two designs including a reference design 1706 and implementation 3 design 1708 showing that the force reduction increases with increasing voltage.

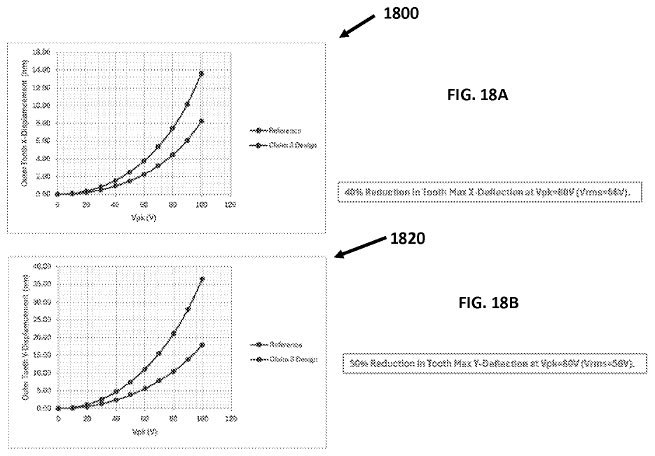

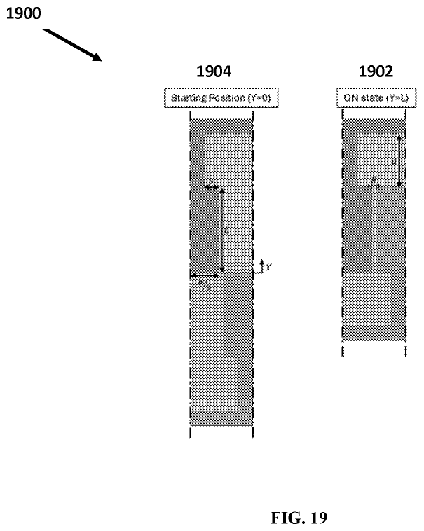

FIGS. 18A and 18B and 19 show the X and Y-direction maximum tooth tip displacement comparison for the designs. Significant reductions of 40% and 50% are achieved respectively at Vpk=80V. This is reduced from the 64% force reduction due to the small reduction in tooth stiffness of the design of FIG. 8. FIGS. 18A and 18B show X-direction and Y-direction deflection graphs 1800 and 1820 comparisons between the reference and implementation 3 designs. FIG. 19 shows the annotated zero force ON state rotor and stator half tooths 1900 in the stating position 1904 and ON state 1902.

It is possible for this example to be further improved to the point of the force crossing the zero-line to realize a position of net-zero force. This can be achieved by increasing the size of the cutout in Feature C and by increasing the effect of Feature D by either increasing tooth height or reducing the height of the connecting beams. An example of this net-zero effect is demonstrated below with an alternative geometry.

Further to the above, an alternative geometry option exists where a zero force, maximal capacitance state can be achieved. By considering a tooth with variable width and/or thickness with the respective gaps chosen such that, upon over-travel, F_{SIDE} (F_S1 in the following text) reverses and cancels the force due to F_{TIP} (relabeled F_{T}). An example geometry that achieves this is shown in FIG. 19.

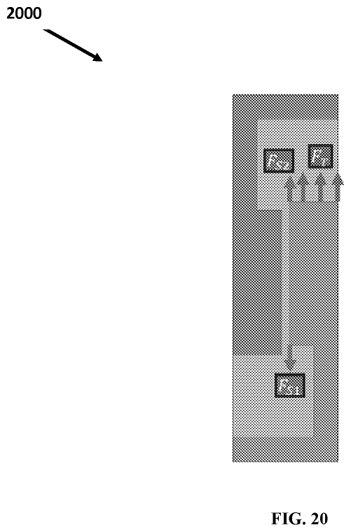

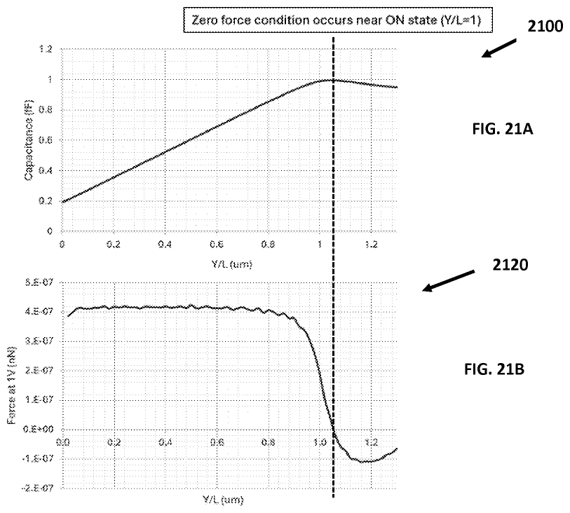

FIG. 20 shows a diagram 2000 of forces acting on the stator at a position of displacement marginally past the ON state. Considering the geometry in FIG. 19 in a position of slightly greater displacement than the ON state (Y>L), the forces on the rotor can be annotated, as shown in FIG. 20. There are three forces acting on the rotor tooth geometry when displaced in the positive Y-direction past the ON state. Identical forces act on the stator, however, for brevity, in this description only the rotor will be considered. It is implicit that, due to symmetry, the conclusions for the forces on the rotor are applicable to the stator also.

The force F_{T} is dependent on d and b whereas, F_{S1} is independent of these quantities. Furthermore, as F_{S1} must be greater than F_{S2} due to the smaller capacitive gap. Therefore, values of d and b may be chosen such that F_{S1}≥F_{T}+F_{S2} in the ON state (Y=L).

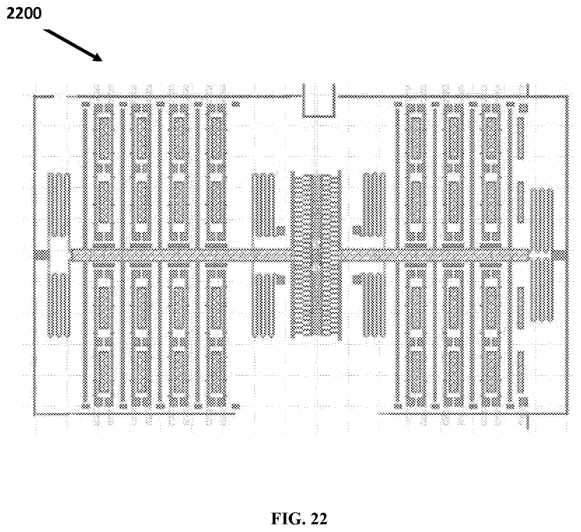

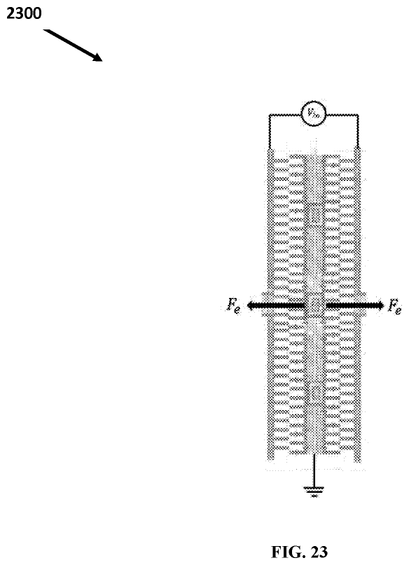

FIGS. 21A and 21B show simulated capacitance and force (at 1V) of the design shown in FIG. 19. The simulated capacitance and force (at 1 volt) for the geometry shown are provided in the plots 2100 and 2120 with a zero-force position occurring near the ON state position, defined in the plot by Y/L=1.

Additional design proposals which achieve similar benefits compared to the standard rotor-stator pair design are also possible provided they follow the physical reasoning for improvement aligns to that of the implementation 3 example designs.

The designs presented in detail within this implementation feature self-alignment/net zero force in the Y-direction. However, this concept can be easily extended to be used in the X- or Z-directions or any of the three principal directions in combination. Specific examples for alignment in the X- and Z-directions are provided below.

The X-direction features a net-zero force by default due to the translational periodicity of the interdigitated structure; the teeth experience an equal and opposite forces on either of the long sides. However, as this occurs at a capacitance minimum it is an unstable equilibrium, meaning small divergences from the perfectly centered (in X-direction) position can lead to the “tooth pull-in” where the tooth collapses into contact with a neighboring tooth. To avoid this, the principles of this implementation can be employed (separately or in combination with the above) by building a raised area above, below or above and below the rotor tooth such that the centralized position becomes a capacitance maximum. This converts the unstable equilibrium position into a stable equilibrium with the advantage that small divergences from the perfectly centered position are resisted by a centering force and contact with adjacent teeth can be avoided.

In the Z-direction, this concept can be employed to avoid curvature or Z-direction pull-in of long fingers. Long fingers can support more teeth and are beneficial for capacitance ratio. However, excessive finger length can result in curvature or high compliance. Centering electrodes can be placed at the tip of the rotor in both the OFF and ON-state positions. These will act to pull the rotor finger to a flat state, perfectly aligned to the stator in the Z-direction.

### Implementation 4—High Capacitance Ratio, Balanced Force Single-Stator-Double-Rotor RF-MEMS Capacitive Switch Designs

An existing capacitive switch implementation described in WO 2024/260995 A1 features a single rotor-single stator pair where the capacitance ratio is fundamentally limited by the parasitic capacitance of the stator. That is, the capacitive coupling of the electrically isolated stator to the base M1 layer, the M6 capping layer and other surrounding features connected to ground. Additionally, in the presence of a high input signal, there is a large attractive force between the rotor and stator which can cause potentially destructive stator deflection.

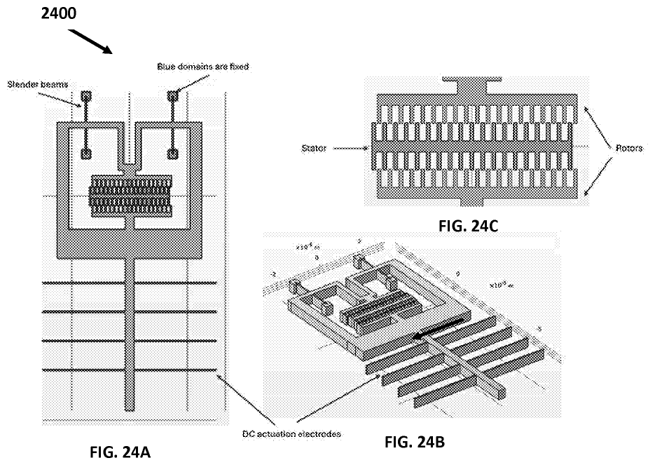

The High Capacitance Ratio, Balanced Force Single-Stator-Double-Rotor capacitive switch that constitutes implementation 4 presents an inventive step that both increases capacitance ratio and eliminates the potentially destructive stator deflection in the presence of high input signals. The device presented in plan view in FIG. 22 features a dual-sided stator. The realization of improvements are summarized below:
The single stator, double rotor approach allows the ON state capacitance to be doubled whilst the parasitic capacitance due to the stator is only incrementally increased by the presence of additional teeth. The anchoring and reinforcement structures are matched to the single rotor case. This leads to an increase in capacitance ratio of approximately 30%.
Furthermore, the device power handling is improved as the potentially destructive stator deflection is mitigated as the attractive rotor-stator force is balanced by an identical attractive force in the opposing direction towards the second rotor. This is depicted in FIG. 23. This eliminates the primary failure mode associated with power handling.

FIG. 22 shows a single-stator double-rotor implementation 2200.

FIG. 23 shows a diagram 2300 of a balanced electrostatic force on a stator due to opposing rotors.

### Implementation 5—Compliant Mechanism Design for a High Capacitance Ratio RF-DTC

A further development of the single-stator-double-rotor design described in implementation 4 is described below where use of a compliant mechanism is employed to achieve the same advantages in a greatly reduced device footprint.

The design presented in FIG. 22, implementation 4, requires opposing directions of motion of the rotors, this is implemented by mirroring the device about the stator. The primary drawback of this approach is the approximate doubling of device area. A separate implementation of the single-stator-double-rotor design is to use a compliant mechanism to drive the second rotor using the same actuators are the first rotor. This implementation is shown in FIGS. 24A, 24B, and 24C. This retains the capacitance ratio and peak voltage advantages of the design of implementation 4 but allows this to be implemented in a much smaller footprint thus increasing the capacitance density.

FIGS. 24A, 24B, and 24C show an arrangement 2400 of various views of a compliant mechanism implementation of a single-stator-double-rotor design.

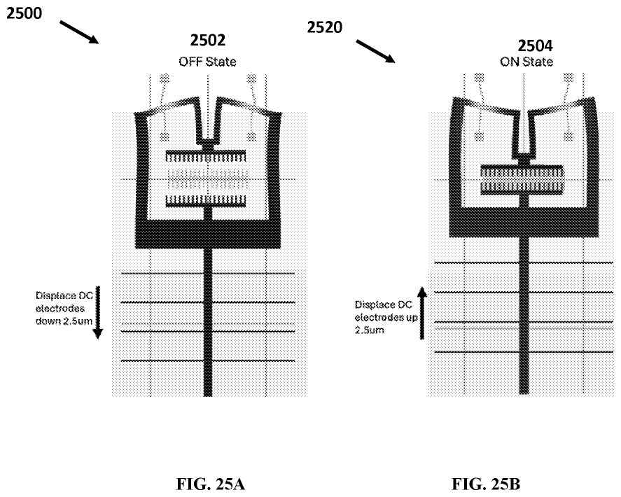

FIGS. 25A and 25B show device deformations 2500 and 2520 in the OFF state 2502 and ON state 2504. FIGS. 25A and 25B present simulations of the device deformation in the OFF and ON states due to downwards and upwards deflection of the DC actuators, respectively. This demonstrates the full range of motion of the opposing rotors can be achieved using a single bank of DC actuators.

### Implementation 6—Internal “Cross-Apex” RF Track Routing for Parasitic Capacitance Minimization

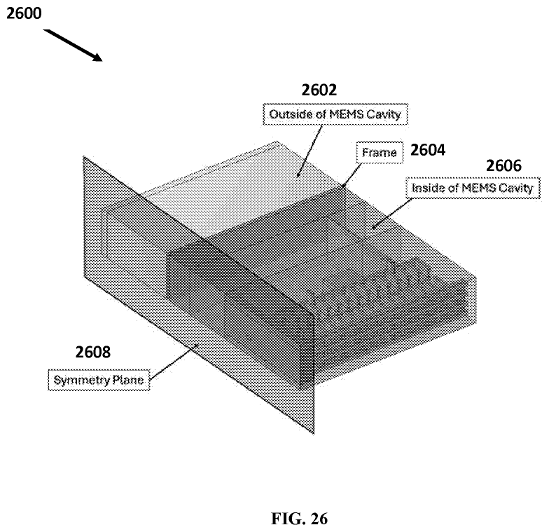

FIG. 26 shows a perspective view inside and outside of a MEMS cavity 2600 that includes and area 2602 outside of the MEMS cavity, a frame 2604, an inside area 2606 of the MEMS cavity, and a symmetry plane 2608.

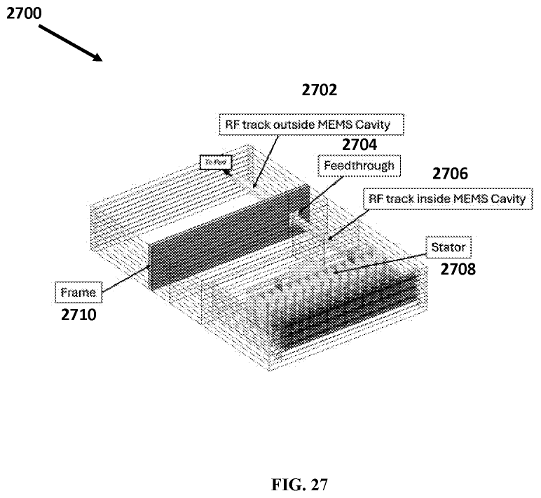

FIG. 27 shows a standard RF track arrangement 2700 with 1 track per stator traveling out of the MEMS cavity. FIG. 27 shows an RF track outside the MEMS cavity 2702, feedthrough 2704, RF track inside the MEMS cavity 2706, stator 2708, and frame 2710.

Device routing is a primary contributor to parasitic capacitance and therefore key factor to be minimized in order to create a high capacitance ratio device. The routing is present in two domains: 1) inside the MEMS cavity and 2) outside the MEMS cavity (FIGS. 26-27). The significant difference being that inside the MEMS cavity the track is enclosed by free-space (and shielded by M1 and M6) and outside the MEMS cavity the track is enclosed by silicon dioxide (and shielded by M1 and M6). This difference leads to an increase in RF track parasitic capacitance outside the cavity in proportion to the relative permittivity of silicon dioxide, that is, 3.9. Therefore, a segment of RF track outside the MEMS cavity contributes 3.9× the parasitic capacitance compared to a segment of RF track inside the MEMS cavity of equal length. In order to maximize capacitance ratio, therefore, it is necessary to include as much routing as possible inside the MEMS cavity, rather than outside.

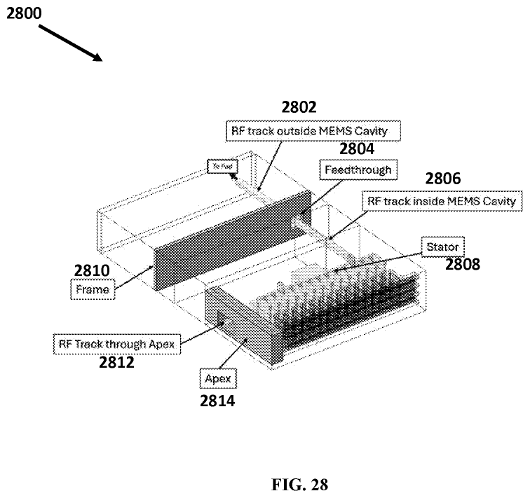

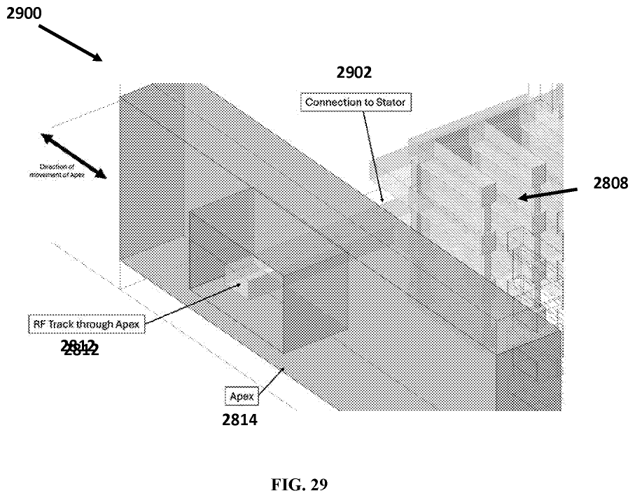

Parasitic capacitance can be reduced by routing the symmetric stators together inside the cavity when compared to two individual tracks serving each stator. This is implemented by implementation 6 whereby the RF track is routing through the apex, a moving component of the device, to connect with the second stator. This implementation is depicted in FIGS. 28-29. This is an extension of the disclosure of WO 2024/260995 A1 detailing internal RF track routing. The RF track could also be routed above or below the Apex by use of a notch in the Apex.

FIG. 28 shows a configuration 2800 having an RF track routed through a MEMS apex 2814 with sufficient space that allows for movement of the apex 2814. In this implementation, symmetry is broken as a second track routed outside of the MEMS cavity is no longer required. The configuration 2800 includes RF track outside the MEMS cavity 2802, feedthrough 2804, RF track inside the MEMS cavity 2806, stator 2808, frame 2810, RF Track through the Apex 2812, and Apex 2814.

FIG. 29 shows a perspective zoomed in view 2900 of the configuration of FIG. 28 including a high capacitance density, double-apex RF MEMS capacitance switch. FIG. 29 shows the connection 2902 to stator 2808 and the RF track 2812 through apex 2814.

Implementation 7—High Capacitance Density, Double-Apex RF MEMS Capacitive Switch

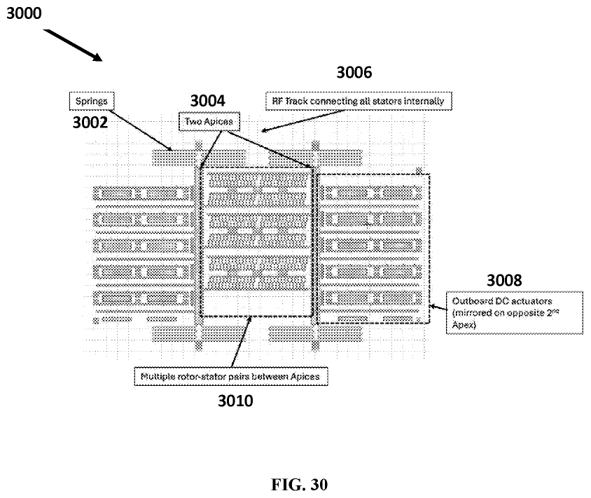

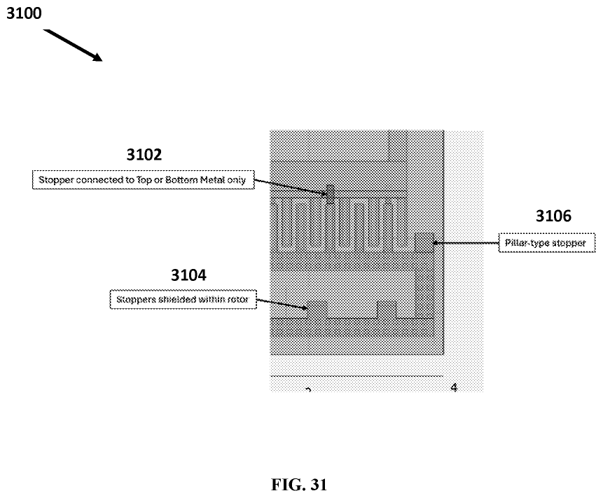

Implementation 7 discloses a high capacitance density implementation of the general design described in WO 2024/260995 A1. An annotated sketch of this implementation is presented in FIG. 30. In this implementation, the device features two apices and a plurality of rotor-stator pairs in the space between the apices. The apices may be mechanically connected so that the actuation force is shared and both receive the total force from the outboard DC actuation arms (reducing the required actuation voltage) or they may be separate, allowing opposing actuation directions. Locating the DC actuation arms outboard of the device enables direct DC routing through the side of the cavity as in the original device. The plurality of stators are routed together internally in order to decrease parasitic capacitance and increase capacitance ratio.

FIG. 30 shows a diagram of a high-capacitance density, double-apex capacitive switch 3000. Switch 3000 includes springs 3002, two apices 3004, RF track 3006 connecting all stators internally, outbound DC actuators 3008 (mirrored on opposite 2^{nd} apex), and multiple rotor-stator pairs 3010 between apices.

### Implementation 8—RF MEMS Mechanical Stoppers

Use of mechanical stoppers to prevent contact between rotor and stator. The stoppers can be implemented as a metal attached to the MEMS cavity by a vias and/or as columns or pillars from the bottom to the top of the MEMS cavity. These stoppers can be placed overlapping the stator or inside the rotor finger or closer to it to act as stoppers of the rotor. All the stoppers can be placed to prevent or limit the displacement of the rotor frontwards and/or backwards and/or laterally. To prevent short circuit between rotor and stoppers all the stoppers will be at the same electrical potential as the rotor. The contact between the rotor and the different types of stoppers will be implemented in a shape that will minimize the contact area to prevent stiction phenomena between the rotor and the stoppers. Some examples of stopper implementations are shown in FIGS. 31-35.

FIG. 31 shows a device 3100 with stopper types and their placement including stopper 3102 connected to top or bottom metal only, stopers 3104 shielded within a rotor, and pillar type stopper 3106.

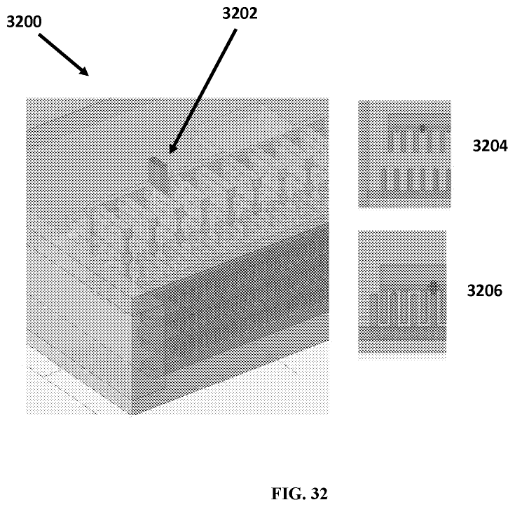

FIG. 32 shows a portion of a switch 3200 where a stopper 3202 is positioned between teeth and only connected to top metal in the ON state 3206 and OFF state 3204.

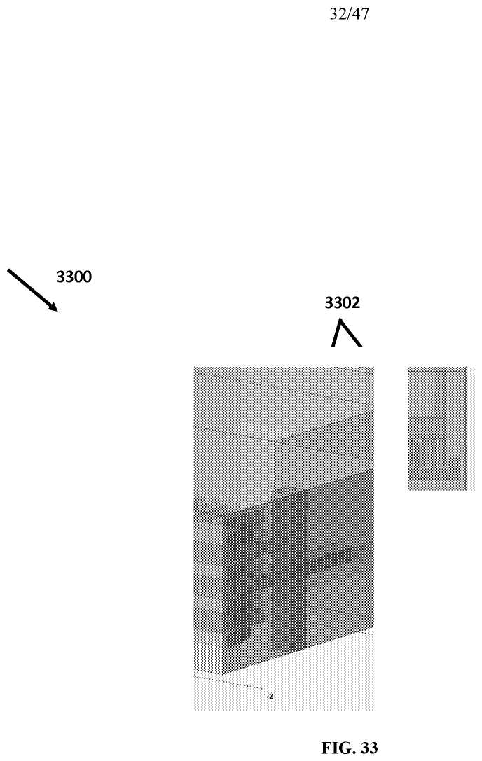

FIG. 33 shows a portion of a switch 3300 with a “pillar-type” stopper 33302 spanning between a bottom metal layer and a top metal layer, and positioned outside of the stator.

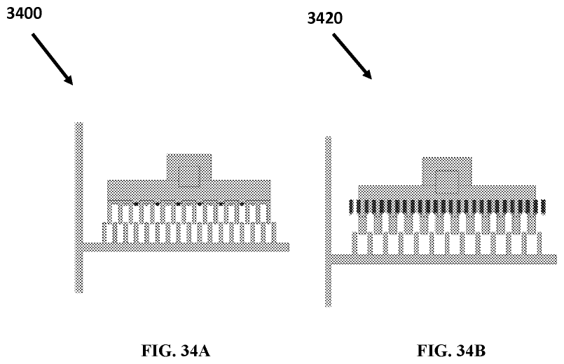

FIGS. 34A and 34B show examples 3400 and 3420 of different stopper shapes respectively in a switch.

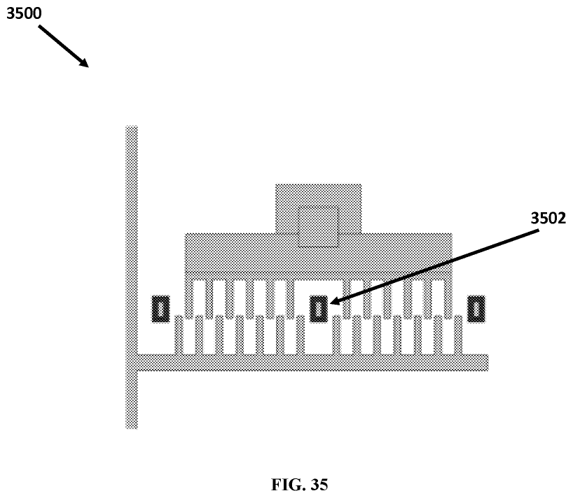

FIG. 35 shows another example 3500 of pillar stopper 3502 placement between teeth or outside of the stator region.

### Implementation 8.1 Shielded Stoppers

Considering an implementation where the spring, apex, rotor assembly is grounded and the stator is connected to the RF signal terminal, grounded “stoppers” are employed to act as a mechanical hard-stop for the rotor in the ON state. A mechanical hard stop serves several purposes: fixing the capacitive gap between the rotor-stator, increasing robustness by limiting deflection in the presence of a high RF signal and increase linearity by limiting harmonic oscillation of the rotor in the ON state.

Any implementation of grounded mechanical hard stop near the stator teeth will result in additional parasitic capacitance leading to a decrease in capacitance ratio. Implementation 8.1 presents an alternative implementation whereby the stoppers are implemented as pillars enclosed within the rotor finger (FIG. 31). In this implementation the grounded stoppers are entirely shielded from the stator and do not contribute any parasitic capacitance and are therefore a beneficial feature of a high capacitance ratio design.

### Implementation 8.2—Mechanical Stopper to Prevent Peak Voltage Limiting Failure in Interdigitated RF MEMS Capacitive Switches

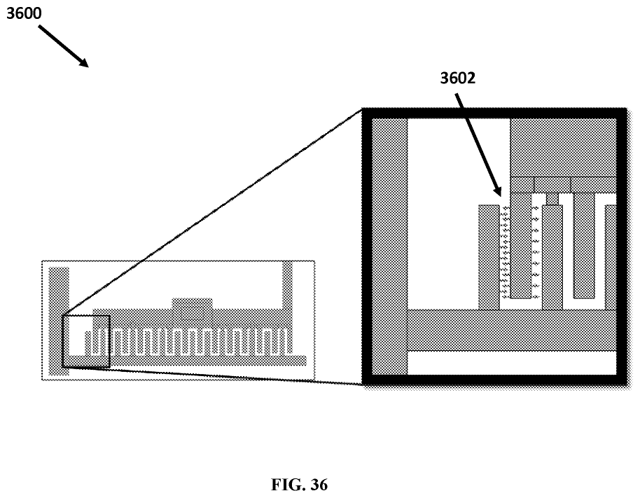

An interdigitated rotor-stator pair features a necessary and inherent point of weakness that is the primary point of failure in the presence of a large RF signal. FIG. 36 depicts the X-direction electrostatic forces on the rotor & stator teeth due to the rotor-stator potential difference. The “inner” teeth experience identical lateral forces due to the translational symmetry (periodicity) of the interdigitated teeth, however, the outer rotor teeth, where the symmetry is necessarily broken, experience an unbalanced force.

FIG. 36 shows the electrostatic forces 3602 experienced by the outermost teeth of a rotor-stator pair 3600.

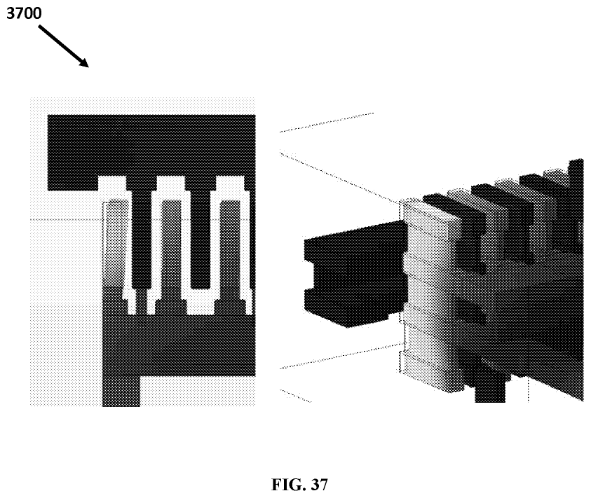

FIG. 37 shows a simulation 3700 of the typical deflection shape of the rotor in the presence of a large RF signal. It can be seen that the outermost teeth experience a far larger deflection towards the stator than the inner teeth. This can lead to arcing or a short circuit between the rotor and stator and is a primary device failure mode.

### Implementation 9—Nonuniform Tooth Width to Prevent Peak Voltage Limiting Failure in Interdigitated RF MEMS Capacitive Switches

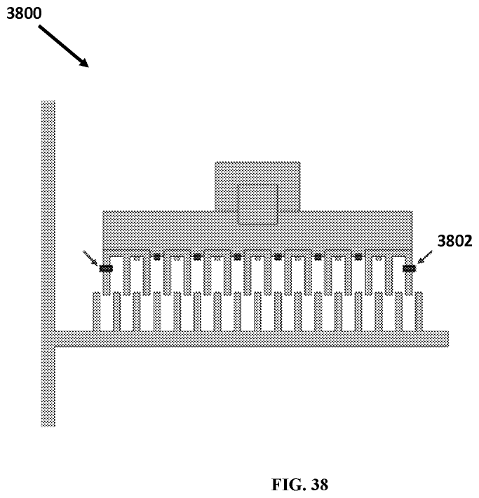

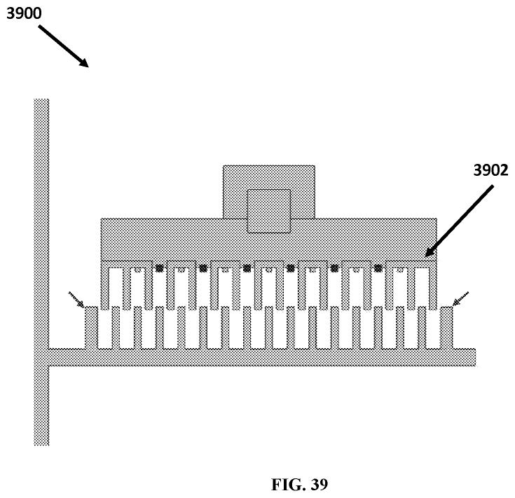

FIG. 38 depicts Implementation 9 which presents a stopper design and placement to prevent this failure mode. FIG. 38 shows a rotor-stator pair with stopper 3802 positioned to prevent failure due to deflection of outermost tooth.

Use of variable tooth widths within the rotor and/or stator teeth arrays. This may be one tooth or multiple teeth, in a periodic or aperiodic pattern. The primary use of this design feature is to prevent the failure described by FIG. 37 of implementation 8.2. Use of a wider tooth on the outermost tooth will limit the deflection due to the unbalanced force this tooth experiences. Whilst the remaining teeth can be narrower, which is beneficial for capacitance ratio. An example of the specific case of this implementation where the wider teeth are the outermost teeth is shown in FIG. 39.

FIG. 39 shows a rotor-stator pair 3900 with teeth 3902 of increased width.

### Implementation 10—Switchable Stoppers for RF MEMS Capacitance Tuning

Typical implementations of a digitally tunable capacitive switch (DTC), such as the one presented in WO 2024/260995 A1 feature several discrete MEMS variable capacitors with fixed ON and OFF state values. These are the individual “bits” that can be used in all combinations to produce a discrete range of capacitance values between the absolute minimum and absolute maximum values. Implementation 10 presents an implementation whereby one or multiple MEMS switchable hard stops are employed to provide intermediate capacitance positions within a single device. This reduces the number of devices required and eliminates a proportion of the RF track routing, enabling capacitance ratios.

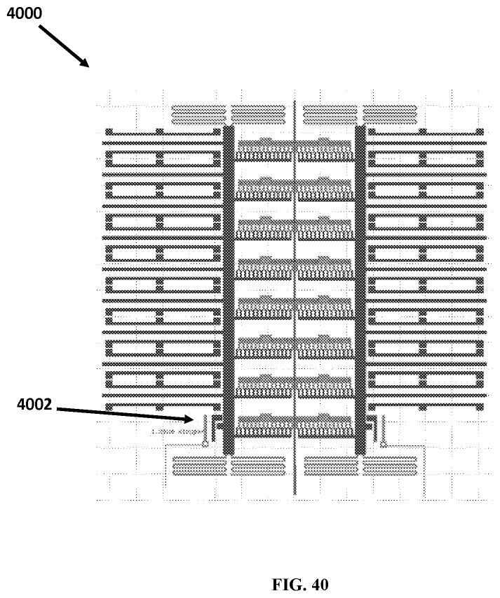

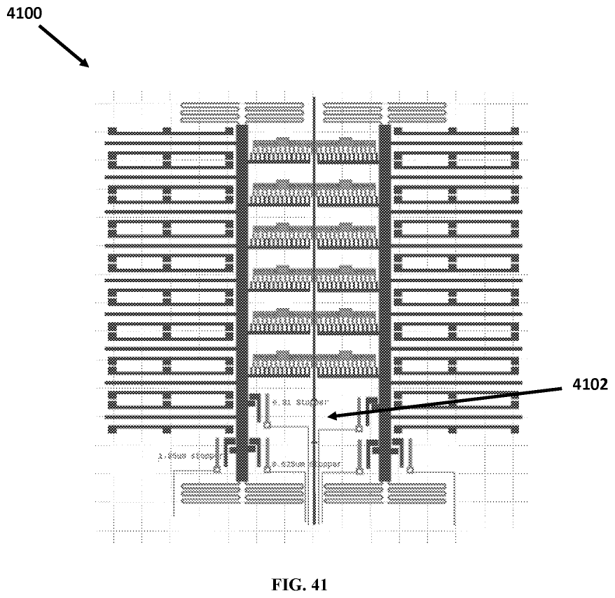

FIG. 40 depicts the proposed implementation 4000 of a single MEMS stopper distance 4002 (with two instances to maintain device symmetry). FIG. 40 device 4000 includes a single MEMS stopper 4002 that enables an intermediate ON state. In this implementation the stoppers can be actuated with a cantilever type actuation to remove the limit they impose on the Apex travel. With no voltage applied to the stopper actuator, the Apex would travel to a point of half tooth overlap. With voltage applied to actuate the stoppers, the Apex would be free to travel to full tooth overlap. The extension from two hard stops to a plurality of hard stops is immediately obvious and therefore this implementation extends to multiple hard stops in a single device, this implementation is shown in FIG. 41.

FIG. 41 shows a device 4100 with multiple MEMS stoppers 4102 and multiple intermediate ON states.

### Implementation 11—Stepped Actuation RF MEMS Capacitive Switch

Typical implementations of a digitally tuneable capacitive switch (DTC), such as the one described in WO 2024/260995 A1, feature several discrete MEMS variable capacitors with fixed ON and OFF state values. These are the individual “bits” that can be used in all combinations to produce a discrete range of capacitance values between the absolute minimum capacitance and the absolute maximum capacitance. Implementation 11 presents an alternative implementation whereby a single device has multiple actuation equilibria allowing the same functionality within a substantially reduced footprint. Furthermore, the reduction from multiple devices to a single device eliminates a large proportion of the RF track routing, leading to increased capacitance ratios.

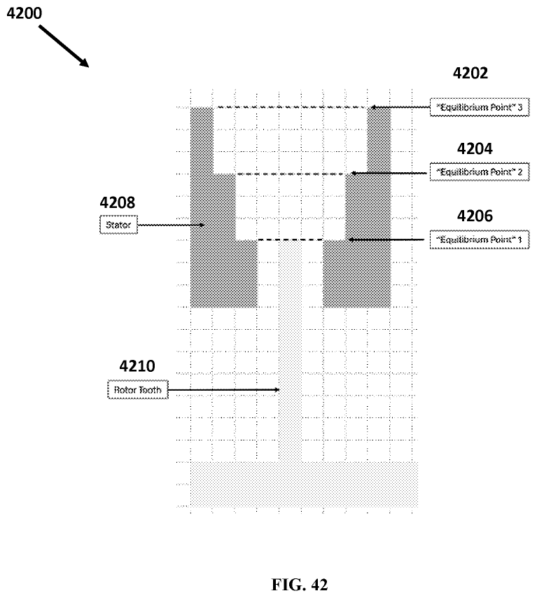

FIG. 42 depicts an interdigitated DC actuator design 4200 featuring multiple local capacitance maxima. Each capacitance maxima corresponds to a notional equilibrium position. For a given spring constant and actuation voltage level the rotor will travel to a chosen equilibrium point including points 4202, 4204, and 4206. As the driving force decreases with advancing rotor tooth position, due to the stepped structure of the stator, a larger actuation voltage level is required to advance the rotor to the next equilibrium position. FIG. 42 shows the stator 4208 and a rotor tooth 4210 of the actuator design 4200.

### Implementation 12—Tensile Aligners

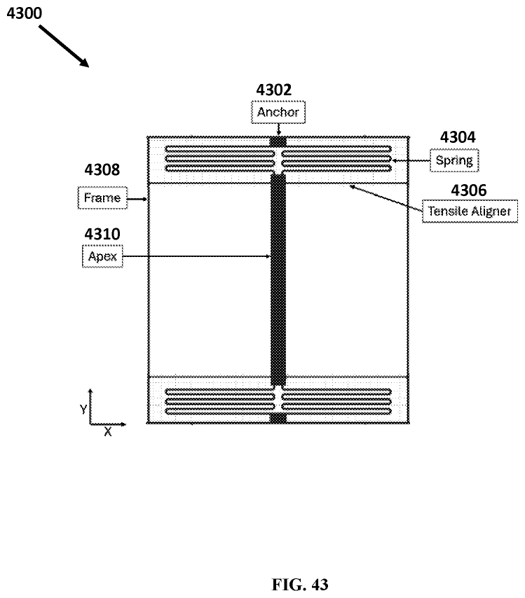

Use of tensile aligners, composed of metal strips attaching the central part of the device (Apex) to the MEMS cavity (frame) in the orthogonal direction of rotor displacement, to guide the rotor displacement and align it to the direction of actuation. These tensile aligners can be composed of one single metal or by a stack of metals and vias. Metal strips can take different shapes to facilitate their alignment function. In a typical implementation, tensile aligners are placed symmetrically about the longitudinal (Y) axis of the apex, however, there is no upper or lower bound on the quantity of tensile aligners that can be placed. A typical configuration is displayed in FIG. 43, however, an alternate implementation may have tensile aligners only at one end of the Apex or a plurality along the length of the Apex.

FIG. 43 shows a MEMS device 4300 including a tensile aligner 4306. Device 4300 also includes a spring 4304, frame 4308, and apex 4310. The functionality of tensile aligner 4306 arises from having a high relative compliance in the Y-direction and a high relative stiffness in the X-direction, as for X-direction displacement to occur, one side must be placed in pure tension.

### Implementation 13—RF MEMS Mechanical Reinforcements

Reinforcements added to the stator and rotor finger to prevent their bending under mechanical and/or electrical stress.

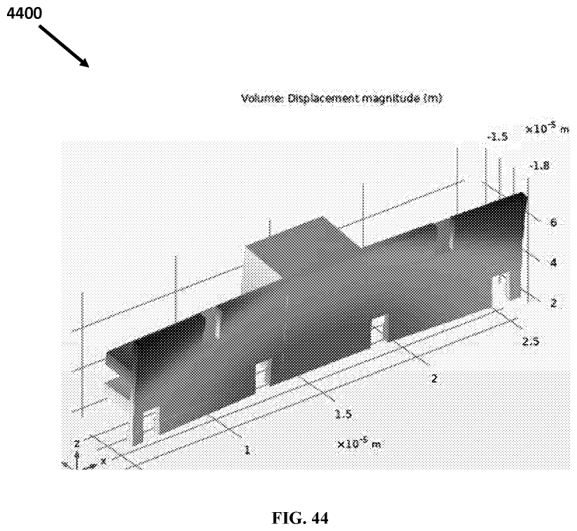

FIG. 44 depicts a simulation 4400 of a stator beam bending under electrostatic force from the rotor (not pictured). Reinforcements can be added to the back of the primary stator beam (that locates the teeth) to minimize this deformation.

In some implementations, a pedestal is positioned above and/or below the teeth, in a similar where an implementation a “pedestal” on each side. While certain implementations may account for Y forces only, vertical pedestals can account for X forces. Otherwise, there may be an a unstable equilibrium with a minimum capacitance, such as a zero derivative, when a tooth is positioned in the middle and with approximately perfect symmetry with respect to the X axis.

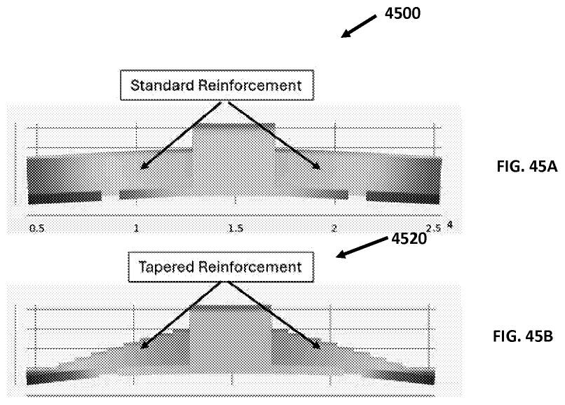

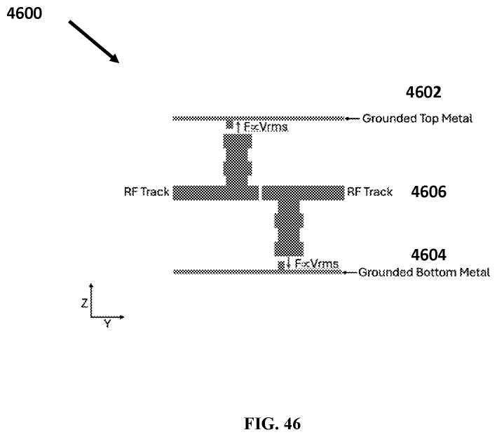

These reinforcements can be of different shapes and use different combinations of metal and/or via layers from a single metal to a stack of metals and vias and they will be attached to the finger to reinforce it mechanically. Furthermore, shapes can be used such as a tapered reinforcement (FIGS. 45A and 45B) to minimize additional parasitic capacitance whilst maintaining mechanical reinforcement.

FIGS. 45A and 45B show examples of standard rectangular reinforcement 4500 vs. tapered reinforcement 4520.

### Implementation 14—RF MEMS ESD Protection Device(s)

The capacitive switch may have a sub micrometer gap at its input for protection in front Electrostatic Discharges (ESD) by allowing the ESD current to pass throw it and avoiding damage due to ESD on the MEMS device.

### Implementation 15—MEMS Peak Voltage Limiter

The RF track will be split into two capacitively coupled components that have a high-coupling capacitance at low values of RF input signal. The RF tracks will have arms connected to them to provide a capacitive connection to the Top and Bottom metals (FIG. 46). The dimensions can be tuned such that, at a critical value of RF input signal, the RF track components are actuated in different directions towards the Top and Bottom metals, respectively. This substantially lowers the coupling capacitance, significantly reducing the signal seen at the rotor-stator pair and avoiding damage to the MEMS device. Once the RF signal is removed, the RF track will recover back to its original, high coupling capacitance, position and normal device operation will resume.

FIG. 46 shows an arrangement 4600 with a peak voltage limiting RF track 4606 with MEMS variable coupling capacitance. The RF track 4606 positioned between a grounded top metal layer 4602 and grounded bottom metal layer 4604.

Implementation 16—RF MEMS Variable Capacitor with Interdigitated DC Actuators

The DC part of the device, that is isolated from the RF part, can be implemented by means of interdigitated electrodes instead of parallel plate electrodes as in previous versions of the devices. This allows for the generation of large, linear actuation forces with less area and/or less voltage. This can also be used large pull off forces to allow device switching while the RF signal is ON (hot switching). Furthermore, this can also be used to reduce switching time when used with a matched area and voltage.

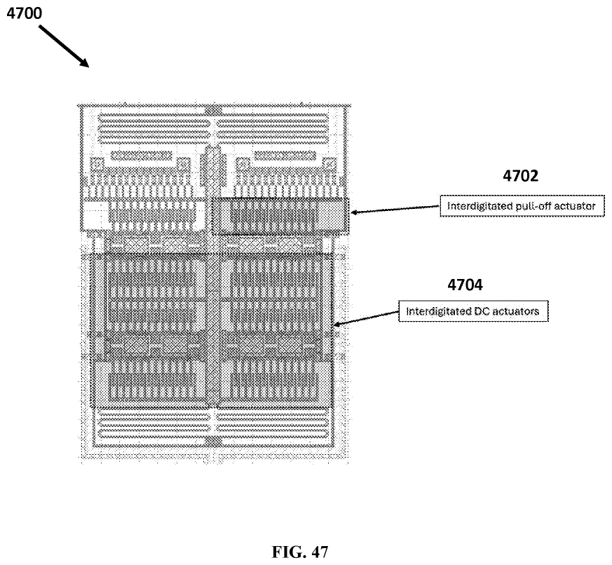

FIG. 47 shows a device 4700 including interdigitated DC actuators 4704 and interdigitated pull-off actuators 4702.

### Implementation 17—RF MEMS Series Connection to Improve Power Handling Performance

Series connection of two or more MEMS-in-CMOS capacitive switches can be used to reduce the voltage drop across each of them. This can be either the connection of MEMS capacitive switches with other MEMS capacitive switches or MEMS capacitive switches with other types of fixed capacitors such as MAM (Metal air Metal), MIM (Metal intermetal dielectric Metal) or MOM (Metal oxide Metal). Multiple series paths or two or more switches may be connected to others in parallel in order to reduce equivalent series resistance (ESR) at the device level.

### Implementation 18—RF MEMS DTC Topology for High Q and High Capacitance Ratio

Several capacitive switches can be connected in an array to form a Digital Tunable Capacitor (DTC). The capacitive switches are connected in a star shape topology connected to the RF signal pad using two or more connection branches to reduce Equivalent Series Resistance (ESR). Connection branches and Pads will be shielded from the substrate by means of any combination of metals and vias to prevent electromagnetic field coupling into the substrate. A group of Capacitive switches actuation electrodes can be connected together to be biased at the same time forming a group known as bit. There can be any number of groups forming different number of bits on a single DTC.

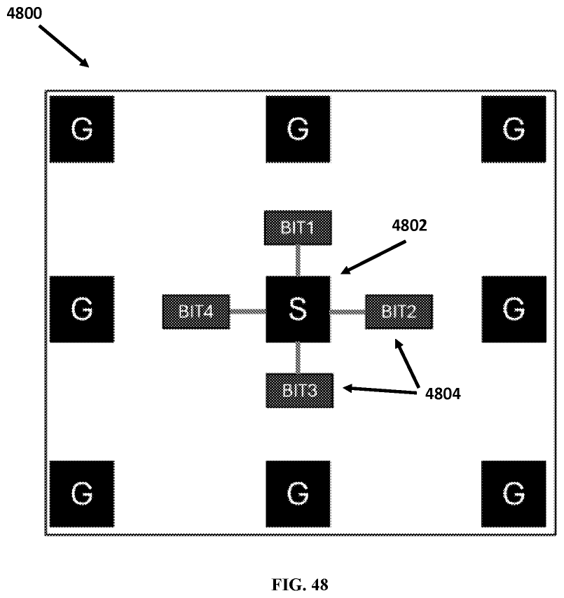

The arrangement of the star shape topology with the DTC bits 4804 encircling the signal input pad 4802 is shown in FIG. 48. The signal pad 4802 could be complemented by a single ground pad or surrounded by multiple ground pads or DC actuation pads.

FIG. 48 shows a device 4800 including a ball grid array (BGA) style chip with a star topology DTC.

In various implementations, devices may be implemented for a MEMS device or an IC device (e.g., only ASIC and no MEMS). Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

1. A RF-MEMS capacitive switch comprising:
at least one stator including stator teeth;
at least one rotor, including rotor teeth, with actuation providing an electrostatic force between the at least one stator and the at least one rotor when a voltage difference is applied between them; and
a central apex connected to the at least one rotor and suspended by means of a plurality of meander springs positioned at distal ends of the central apex.

2. The capacitive switch of claim 1, wherein the capacitive switch has a capacitance ratio ≥5 and maximum peak voltage ≥80V.

3. The capacitive switch of claim 1 comprising an etch-limiting capacitive anchor having a flap implemented on a metal layer.

4. The capacitive switch of claim 3, wherein the flap is implemented on the M2 layer.

5. The capacitive switch of claim 1, comprising a pillarless capacitive anchor.

6. The capacitive switch of claim 1, wherein the at least one rotor and the at least one stator are configured to reduce the electrostatic force needed to actuate the capacitive switch.

7. The capacitive switch of claim 6, wherein material in at least one of the rotor teeth and stator teeth that does not overlap its opposing teeth does not include a full stack of metals.

8. The capacitive switch of claim 6 comprising a support beam, wherein the support beam does not include a full stack of metals.

9. The capacitive switch of claim 6 comprising a support beam, wherein the support beam is notched by an amount equal to the size of a gap directly in front of a tooth of the rotor teeth from an opposing tooth of the stator teeth.

10. The capacitive switch of claim 6, wherein material from all layers of the capacitive switch is present in a portion of a tooth of the rotor teeth that overlaps an adjacent tooth of the stator teeth at the point of maximum overlap with the capacitive switch is in an ON state, but minimized in all layers of the capacitive switch in regions that do not overlap.

11. A MEMS-based device comprising:
at least one stator including stator teeth; and
at least one rotor, including rotor teeth, with actuation providing an electrostatic force between the at least one stator and the at least one rotor when a voltage difference is applied between them.

12. The MEMS-based device of claim 11, wherein the MEMS-based device has a capacitance ratio ≥5 and maximum peak voltage ≥80V.

13. The MEMS-based device of claim 11 comprising an etch-limiting capacitive anchor having a flap implemented on the M2 metal layer.

14. The MEMS-based device of claim 11, comprising a pillarless capacitive anchor.

15. The MEMS-based device of claim 11, wherein the at least one rotor and the at least one stator are configured to reduce the electrostatic force needed to actuate the MEMS-based device.

16. The MEMS-based device of claim 15, wherein material in at least one of the rotor teeth and stator teeth that does not overlap its opposing teeth does not include a full stack of metals.

17. The MEMS-based device of claim 15 comprising a support beam, wherein the support beam does not include a full stack of metals.

18. The MEMS-based device of claim 15 comprising a support beam, wherein the support beam is notched by an amount equal to the size of a gap directly in front of a tooth of the rotor teeth from an opposing tooth of the stator teeth.

19. The MEMS-based device of claim 15, wherein material from all layers of the MEMS-based device is present in a portion of a tooth of the rotor teeth that overlaps an adjacent tooth of the stator teeth at the point of maximum overlap with the MEMS-based device is in an ON state, but minimized in all layers of the capacitive switch in regions that do not overlap.

20. The MEMS-based device of claim 15 comprising a stopper positioned adjacent to a tooth of at least one of the rotor teeth and the stator teeth.
